(19) United States
(12) Patent Application Publication
(10) Pub. No.: US 2024/0365643 A1
(43) Pub. Date: Oct. 31, 2024

(54) DISPLAY SUBSTRATE AND DISPLAY APPARATUS

(71) Applicants: Chengdu BOE Optoelectronics Technology Co., Ltd., Sichuan Province (CN); BOE Technology Group Co., Ltd., Beijing (CN)

(72) Inventors: Zeliang LI, Beijing (CN); Tao GAO, Beijing (CN)

(21) Appl. No.: 18/292,500

(22) PCT Filed: Jan. 3, 2023
(86) PCT No.: PCT/CN2023/070188

§ 371 Date: Jan. 26, 2024

(30) Foreign Application Priority Data
Jan. 26, 2022 (CN) 202210096252.3

(51) Int. Cl. H10K 59/80; G06F 3/041; G06F 3/044; H10K 59/131; H10K 59/40

(52) U.S. Cl. CPC H10K 59/873; G06F 3/0412; G06F 3/04164; G06F 3/0445; H10K 59/131; H10K 59/40; G06F 3/0446; G06F 2203/04111

(57) ABSTRACT

A display substrate and a display apparatus. The display substrate includes a base substrate, including a display area, non-display areas around the display area; a dam in the non-display areas and partially around the display area; power lines in the non-display area on one side of the display area, the power lines including integrally arranged first and second parts, orthographic projections of the first parts coinciding with orthographic projection of the dam on the base substrate, and orthographic projections of the second parts being non-overlapping with orthographic projection of the dam on the base substrate; an anode conductive layer on the side away from the base substrate, of the layer where the power lines are, the anode conductive layer including a protection structure partially in the non-display area, and covering part of edges of the second parts.

### CROSS REFERENCE TO RELATED APPLICATION

The present disclosure is a National Stage of International Application No. PCT/CN2023/070188, filed on Jan. 3, 2023, which claims priority to Chinese Patent Application No. 202210096252.3, filed with China National Intellectual Property Administration on Jan. 26, 2022 and entitled “Display Substrate and Display Apparatus”, the entire contents of which are incorporated herein by reference.

### TECHNICAL FIELD

The present disclosure relates to the field of a display technology, in particular to a display substrate and a display apparatus.

### BACKGROUND

In recent years, organic electroluminescence display (OLED), as a new type of flat panel display, has gradually received more attention. Due to its excellent characteristics such as active luminescence, high luminance brightness, high resolution, wide viewing angle, fast response speed, small thickness, low energy consumption, flexibility, wide temperature range, simple structure and manufacturing process, etc., it has broad application prospects.

### SUMMARY

Embodiments of the present disclosure provide a display substrate and a display apparatus, and the specific solutions are as follows.

On the one hand, the embodiments of the present disclosure provide a display substrate, including:
a base substrate, including a display region and a non-display region disposed around the display region;
a barrier dam, located in the non-display area and at least partially disposed around the display area;
a power line, in the non-display area on a side of the display area; where the power line includes a first segment and a second segment integrally arranged, an orthographic projection of the first segment on the base substrate roughly coincides with an orthographic projection of the barrier dam on the base substrate, and an orthographic projection of the second segment on the base substrate does not overlap with the orthographic projection of the barrier dam on the base substrate; and
an anode conductive layer, located at a side, away from the base substrate, of a layer where the power line is located, where the anode conductive layer includes a protection structure at least partially located in the non-display area, and the protection structure at least covers at least part of an edge of the second segment.

In some embodiments, in the above mentioned display substrate provided by the embodiments of the present disclosure, the protection structure completely covers the second segment.

In some embodiments, in the above mentioned display substrate provided by the embodiments of the present disclosure, the protection structure covers the edge of the second segment and exposes the remaining area of the second segment.

In some embodiments, in the above mentioned display substrate provided by the embodiments of the present disclosure, further including a first source-drain metal layer disposed between the base substrate and the anode conductive layer, and the power line includes a first sub-power line located in the first source-drain metal layer.

In some embodiments, in the above mentioned display substrate provided by the embodiments of the present disclosure, further including a second source-drain metal layer disposed between the first source-drain metal layer and the anode conductive layer; and the power line further includes a second sub-power line located in the second source-drain metal layer, and the second sub-power line at least covers an edge of the first sub-power line.

In some embodiments, in the above mentioned display substrate provided by the embodiments of the present disclosure, the second sub-power line completely covers the first sub-power line.

In some embodiments, in the above mentioned display substrate provided by the embodiments of the present disclosure, the second sub-power line covers the edge of the first sub-power line and exposes the remaining area of the first sub-power line.

In some embodiments, in the above mentioned display substrate provided by the embodiments of the present disclosure, the protection structure at least covers at least part of the edge of the second segment of the second sub-power line.

In some embodiments, in the above mentioned display substrate provided by the embodiments of the present disclosure, the protection structure further at least covers at least part of the edge of the first segment.

In some embodiments, in the above mentioned display substrate provided by the embodiments of the present disclosure, the power line includes a first-level power line and a second-level power line, where the protection structure is disconnected at a gap between the first-level power line and the second-level power line.

In some embodiments, in the above mentioned display substrate provided by the embodiments of the present disclosure, an edge of the first segment and/or an edge of the second segment include an irregular structure.

In some embodiments, in the above mentioned display substrate provided by the embodiments of the present disclosure, a shape of an edge of the protection structure is substantially the same as a shape of an edge of the second segment.

In some embodiments, in the above mentioned display substrate provided by the embodiments of the present disclosure, the non-display area includes a first non-display area for binding with a chip, where the first non-display area includes a encapsulation area and a water-oxygen isolation area arranged in sequence in a direction away from the display area; and the barrier dam in the first non-display area is located in the encapsulation area, and the second segment is located in the encapsulation area and the water-oxygen isolation area.

In some embodiments, in the above mentioned display substrate provided by the embodiments of the present disclosure, the first non-display area further includes a fan-out area and a binding area, where the fan-out area connects with the water-oxygen isolation area and the binding area; and the power line further includes a third segment located in the fan-out area, and the third segment is integrated with the second segment.

In some embodiments, in the above mentioned display substrate provided by the embodiments of the present disclosure, further including a planarization layer disposed between the layer where the power line is located and the anode conductive layer, and the planarization layer is provided on an entire surface of the fan-out area.

In some embodiments, in the above mentioned display substrate provided by the embodiments of the present disclosure, the protection structure further at least covers at least part of an edge of the third segment.

In some embodiments, in the above mentioned display substrate provided by the embodiments of the present disclosure, further including a plurality of touch lines located in the non-display area; the plurality of touch lines is located at a side, away from the base substrate, of a layer where the barrier dam is located; an orthographic projection of at least part of the touch lines on the base substrate and the orthographic projection of the power line on the base substrate overlap each other, and the protection structure is at least partially located at an overlapping area.

In some embodiments, in the above mentioned display substrate provided by the embodiments of the present disclosure, at least some of the touch lines include a conductive winding part, so that resistances of the touch lines are approximately the same, and an orthographic projection of the conductive winding part on the base substrate is located between the orthographic projection of the barrier dam on the base substrate and the display area.

In some embodiments, in the above mentioned display substrate provided by the embodiments of the present disclosure, further including a bridging layer and a touch layer insulated from each other, where the bridging layer is disposed between the layer where the barrier dam is located and the touch layer; and the touch control line includes a first sub-touch line and a second sub-touch line electrically connected with each other, where the first sub-touch line is located in the bridging layer, and the second sub-touch line is located in the touch layer.

In some embodiments, in the above mentioned display substrate provided by the embodiments of the present disclosure, further including a plurality of touch electrodes located in the display area; the touch electrodes are electrically connected with the touch lines; the touch electrodes include first sub-touch electrodes and second sub-touch electrodes electrically with each other, where the first sub-touch electrodes are located in the bridging layer, and the second sub-touch electrodes are located in the touch layer.

In some embodiments, in the above mentioned display substrate provided by the embodiments of the present disclosure, further including an insulating layer between the touch layer and the bridging layer; the insulating layer includes a plurality of through holes, and the first sub-touch electrodes connect with the second sub-touch electrodes through the through holes, and the plurality of through holes are uniformly distributed in the display area.

In some embodiments, in the above mentioned display substrate provided by the embodiments of the present disclosure, the plurality of touch electrodes includes a plurality of first touch electrodes extending along a first direction, and a plurality of second touch electrodes extending along a second direction; the plurality of touch lines include a plurality of first touch lines and a plurality of second touch lines; where, the first touch electrodes are electrically connected with the first touch lines, and the second touch electrodes are electrically connected with the second touch lines.

In some embodiments, in the above mentioned display substrate provided by the embodiments of the present disclosure, the non-display area includes a first non-display area and a second non-display area opposite to each other, and a third non-display area and a fourth non-display area opposite to each other; where the first non-display area is a first non-display area for binding with the chip, the third non-display area and the fourth non-display area are connected with the first non-display area and the second non-display area, respectively;
the plurality of second touch lines extend from the third non-display area and the fourth non-display area, and then are folded to extend toward the first non-display area; and
some of the first touch lines pass through the second non-display area and the third non-display area in sequence and are folded to extend toward the first non-display area, and the remaining first touch lines sequentially pass through the second non-display area and are folded to extend toward the first non-display area; and in the third non-display area and the fourth non-display area, the first touch lines are located at a side of the second touch lines away from the display area.

In some embodiments, in the above mentioned display substrate provided by the embodiments of the present disclosure, the non-display area includes a first non-display area and a second non-display area opposite to each other, and a third non-display area and a fourth non-display area opposite to each other; where the first non-display area is the first non-display area for binding with the chip, the third non-display area and the fourth non-display area are connected with the first non-display area and the second non-display area respectively;
the plurality of second touch lines extend from the fourth non-display area, and then folded to extend toward to the first non-display area; and
some of the first touch lines pass through the second non-display area and the third non-display area and are folded to extend toward the first on-display area, and the remaining first touch lines are located in the first non-display area.

In some embodiments, in the above mentioned display substrate provided by the embodiments of the present disclosure, further including at least one touch chip, and the plurality of touch lines are bound and connected with the touch chip.

On the other hand, the embodiments of the present disclosure provide a display apparatus, including the above mentioned display substrate provided by the embodiments of the present disclosure.

### BRIEF DESCRIPTION OF FIGURES

FIG. 1 is an electron micrograph image of a power line undergoing lateral corrosion of the power line in the related art.

FIG. 2 is a schematic structural diagram of a display substrate provided by an embodiment of the present disclosure.

FIG. 3 is an enlarged structural diagram of the Z1 area in FIG. 2.

FIG. 4 is an enlarged structural diagram of the Z2 area in FIG. 3.

FIG. 5 is a sectional view along line I-I′ in FIG. 4.

FIG. 6 is a sectional view along line II-II′ in FIG. 4.

FIG. 7 is an electron microscope image of a power line without lateral corrosion provided by an embodiment of the present disclosure.

FIG. 8 is a schematic diagram of a protection structure covering a power line provided by an embodiment of the present disclosure.

FIG. 9 is a sectional view along line III-III′ in FIG. 8.

FIG. 10 is another sectional view along line I-I′ in FIG. 4.

FIG. 11 is another sectional view along line III-III′ in FIG. 8.

FIG. 12 is another sectional view along line I-I′ in FIG. 4.

FIG. 13 is another sectional view along line III-III′ in FIG. 8.

FIG. 14 is another schematic diagram of a protection structure covering a power line provided by an embodiment of the present disclosure.

FIG. 15 is a sectional view along line IV-IV′ among FIG. 14.

FIG. 16 is another enlarged structural diagram of the Z1 area in FIG. 2.

FIG. 17 is an enlarged structural diagram of the Z3 area in FIG. 16.

FIG. 18 is a sectional view along line V-V′ among FIG. 17.

FIG. 19 is another enlarged structural diagram of the Z2 area in FIG. 3.

FIG. 20 is another enlarged structural diagram of the Z2 area in FIG. 3.

FIG. 21 is a sectional view along line VI-VI″ in FIG. 20.

FIG. 22 is another enlarged structural diagram of the Z2 area in FIG. 3.

FIG. 23 is a sectional view along line VII-VII″ in FIG. 22.

FIG. 24 is another enlarged structural diagram of the Z2 area in FIG. 3.

FIG. 25 is an electron micrograph image of a bridging layer shorted with a power line in the related art.

FIG. 26 is a sectional view along line VIII-XIII″ in FIG. 24.

FIG. 27 is a schematic diagram of a touch electrode in the present disclosure.

FIG. 28 is a schematic diagram of a bridging layer in FIG. 25.

FIG. 29 is a schematic diagram of a touch layer in FIG. 25.

FIG. 30 is another schematic structural diagram of a display substrate provided by an embodiment of the present disclosure.

FIG. 31 is another schematic structural diagram of a display substrate provided by an embodiment of the present disclosure.

FIG. 32 is another schematic structural diagram of a display substrate provided by an embodiment of the present disclosure.

FIG. 33 is schematic diagram of a partial structural of a barrier dam.

FIG. 34 is another sectional view along line I-I′ in FIG. 4.

FIG. 35 is another sectional view along line III-III′ in FIG. 8.

FIG. 36 is another sectional view along line I-I′ in FIG. 4.

FIG. 37 is another sectional view along line III-III′ in FIG. 8.

FIG. 38 is another sectional view along line IV-IV' in FIG. 14.

FIG. 39 is another sectional view along line I-I′ in FIG. 4.

FIG. 40 is another sectional view along line I-I′ in FIG. 4.

FIG. 41 is another sectional view along line I-I′ in FIG. 4.

FIG. 42 is another sectional view along line I-I′ in FIG. 4.

FIG. 43 is another sectional view along line III-III′ in FIG. 8.

FIG. 44 is another sectional view along line III-III′ in FIG. 8.

FIG. 45 is another sectional view along line III-III′ in FIG. 8.

FIG. 46 is another sectional view along line III-III′ in FIG. 8.

FIG. 47 is another sectional view along line IV-IV′ in FIG. 14.

FIG. 48 is a schematic structural diagram of one sub-pixel in the display area.

### DETAILED DESCRIPTION

In order to make the purpose, technical solutions and advantages of the embodiments of the present disclosure clearer, the technical solutions of the embodiments of the present disclosure will be clearly and completely described below in conjunction with drawings of the embodiments of the present disclosure. It should be noted that that the size and shape of each figure in the drawings do not reflect the true scale, but are only intended to illustrate the present disclosure. And the same or similar reference numerals represent the same or similar elements or elements having the same or similar functions throughout.

Unless otherwise defined, technical or scientific terms used in the present disclosure shall have the ordinary meanings as understood by those with ordinary skills in the art to which the present disclosure belongs. Words “first”, “second” and similar words used in the present disclosure do not indicate any order, quantity or importance, but are only used to distinguish different assemblies. Word “comprise” or “include” or other similar words mean that the element or item appearing before the word encompasses the element or item listed after the word and its equivalents, but does not exclude other elements or items. Words “upper”, “lower”, “left”, “right”, etc., are merely used to indicate a relative position relation, which may also change accordingly when an absolute position of a described object changes.

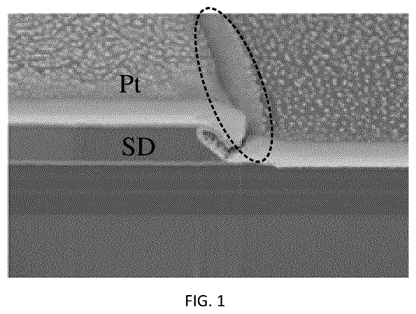

The OLED display panel in the related art includes a base substrate, and a driving circuit, a light emitting device, a barrier dam and a power line arranged on the base substrate, where the driving circuit and the light emitting device are located at a display area, and the barrier dam and the power line are located at an non-display area, and the barrier dam spans the power line. The power line is usually made of a source-drain metal layer of a transistor contained in the driving circuit, and the barrier dam is usually made of an organic insulating layer located at a side of the driving circuit away from the base substrate. In order to form the barrier dam, the organic insulating layer near the barrier dam needs to be removed, resulting in only an inorganic insulating layer covering the power lines near the barrier dam. In the subsequent process of making the transfer electrode (CE, used to connect the driving circuit and the light emitting device), it is necessary to form the transfer electrode (CE) through an etching process, but this etching process will cause over-etching of the inorganic insulating layer and expose out the side of the power line. The etchant of the anode (AND) contained in the light emitting device will come into contact with the exposed side of the power line, causing corrosion (an undercut) at the side, as shown in FIG. 1. Specifically, platinum (Pt) in FIG. 1 is sprayed for testing the side corrosion phenomenon of the power line (SD). It can be seen from FIG. 1 that the platinum (Pt) is fractured on the side of the power line (SD) (the dotted box area in FIG. 1), thus confirming the existence of side corrosion. After the side of the power line is corroded, water and oxygen will flow into the display area along the corroded side of the power line, which will cause package reliability failure (GDSX) and poor dark spots.

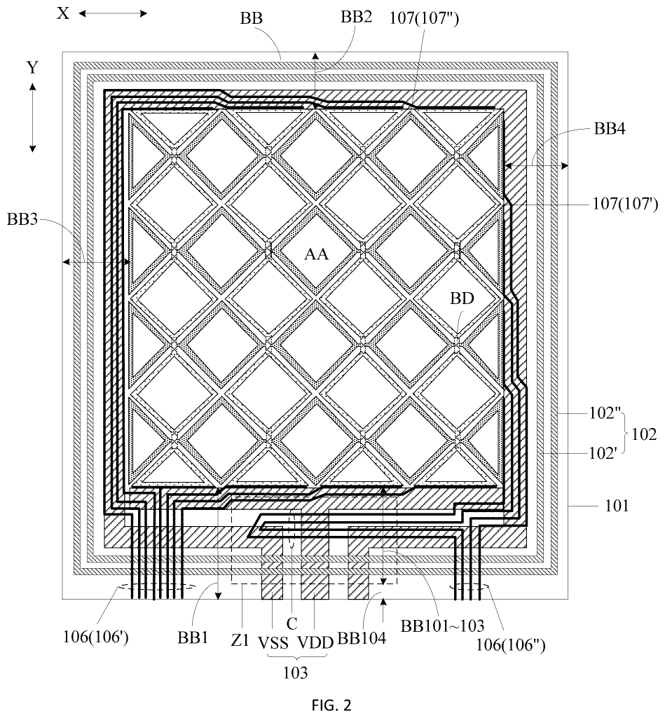

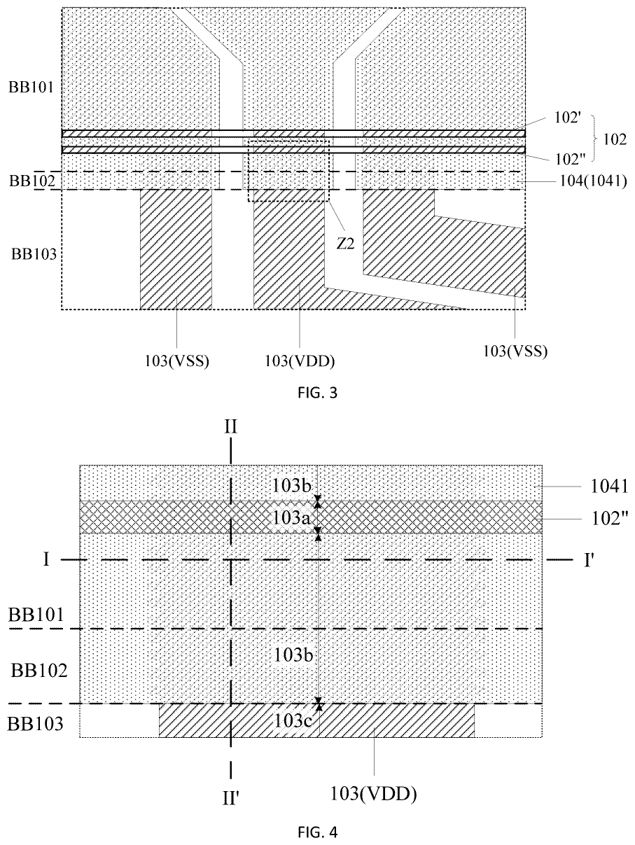

In order to solve the above-mentioned technical problems existing in related art, the embodiments of the present disclosure provide a display substrate, as shown in FIG. 2 to FIG. 6, including:
a base substrate 101, including a display area AA and a non-display area BB disposed around the display area AA;
a barrier dam 102, located in the non-display area BB and disposed around the display area AA;
a power line 103, in the non-display area BB on a side of the display area AA; here, the power line 103 includes a first segment 103a and a second segment 103b that are integrally arranged, and an orthographic projection of the first segment 103a on the base substrate 101 roughly coincides with an orthographic projection of the barrier dam 102 on the base substrate 101, and an orthographic projection of the second segment 103b on the base substrate 101 does not overlap with the orthographic projection of the barrier dam 102 on the base substrate 101; and
an anode conductive layer 104, located at a side, away from the base substrate 101, of a layer where the power line 103 is located. The anode conductive layer 104 includes a protection structure 1041 at least partially located in the non-display area BB, and the protection structure 1041 at least covers at least part of an edge(s) of the second segment 103b. Further, the protection structure 1041 at least covers an edge(s) of the second segment 103b, which is equivalent to protection structure 1041 at least being in contact with a side surface of the second segment 103b and an upper surface (i.e., a part of a surface of the side away from the base substrate) of the second segment 103b adjacent to the side surface.

In the above-mentioned display substrate provided by the embodiment of the present disclosure, the second segment 103b of the power line 103 is not covered by the barrier dam 102, and the present disclosure is provided with the protection structure 1041 that at least covers at least part of the edge(s) of the second segment 103b, and a protection structure 1041 at least covers the edge(s) of the second segment 103b.

In some embodiments, the protection structure 1041 is disposed at the anode conductive layer 104, so that the anode of the anode conductive layer 104 and the protection structure 1041 can be prepared by one etching process, so as to avoid corrosion of the edge(s) of the second division 103b by the etching solution used in the etching process of the anode. Moreover, because the first segment 103a of the power line 103 is covered by the barrier dam 102, the barrier dam 102 may play a protective role to the first segment 103a, so that the first segment 103a is protected from the corrosion by the etching solution used for the anode, thus effectively improving the package reliability and solving the problem of poor dark spots. In order to test whether the power line 103 (SD) has side corrosion, the present disclosure also sprays a layer of platinum (Pt) on the power line 103 covered by the protection structure 1041, and the result is shown in FIG. 7. It can be seen from FIG. 7 that the platinum (Pt) is not broken on the side of the power line 103 (SD) (the dotted frame area in FIG. 7), thus confirming that the protection structure 1041 has well prevented the side corrosion.

In addition, since the edge(s) of the second segment 103b is protected by the protection structure 1041 of the anode conductive layer 104, there is no need to set the inorganic insulating layer used to protect the power line 103 in the related art, so as to save the mask process of the inorganic insulating layer, and reduce the number of film layers, which is conducive to improving production efficiency, reducing production costs, and thinning the design of products.

In some embodiments, at least part of an edge(s) of the first segment 103a may also be provided with a protection structure 1041 to further prevent the first segment 103a from being corroded by the etching solution used for the anode.

In some embodiments, in the above display substrate provided by the embodiments of the present disclosure, as shown in FIG. 2 and FIG. 6, the barrier dam 102 may include a first barrier dam 102′ and a second barrier dam 102″, the second barrier 102″ surrounds the first barrier dam 102′, and the first barrier dam 102′ and the second barrier dam 102″ can be a multi-layer structure, and the multi-film layers are respectively disposed in a first planarization layer (PLN1), a second planarization layer (PLN2), a pixel definition layer (PDL) and a support layer (PS), to maximize the extension of the water and oxygen invasion path and improve the packaging reliability. Of course, in specific implementation, the barrier dam 102 is not limited to the above-mentioned film layer structure, and may include at least one layer structure set in the same layer as a film layer in the display area AA. The barrier dam 102 may also be one, or more than two, and a film layer included in each barrier dam 102 may be the same or different, the number of film layers may be the same or different, and a height of each barrier dam 102 may be the same or different.

The barrier dam 102 may be a fully enclosed structure or include a partially discontinuous void. In some embodiments, as shown in FIG. 32, a portion, near the first non-display area BB1, of at least one barrier dam 102 of the display substrate is bifurcated to form two barrier sub-dams, and the left and right sides of the barrier dam 102 may be substantially symmetrical. Thus at least one barrier dam 102 forms two barrier sub-dams between the display area AA and the bending area BD, which is more helpful to prevent the first planarization layer (PLN1) from entering the bending area BD. When the display substrate includes two or more barrier dams 102, a portion of, near the first non-display area BB1, of the barrier dams 102 close to the display area AA can be bifurcated to form two barrier sub-dams. In the embodiment shown in FIG. 32, the display substrate includes a first barrier dam 102′ and a second barrier dam 102′ located at a side of the first barrier dam 102′ away from the display area AA, and a portion, close to the first non-display area BB1, of the first barrier dam 102′ is bifurcated to form two barrier sub-dams.

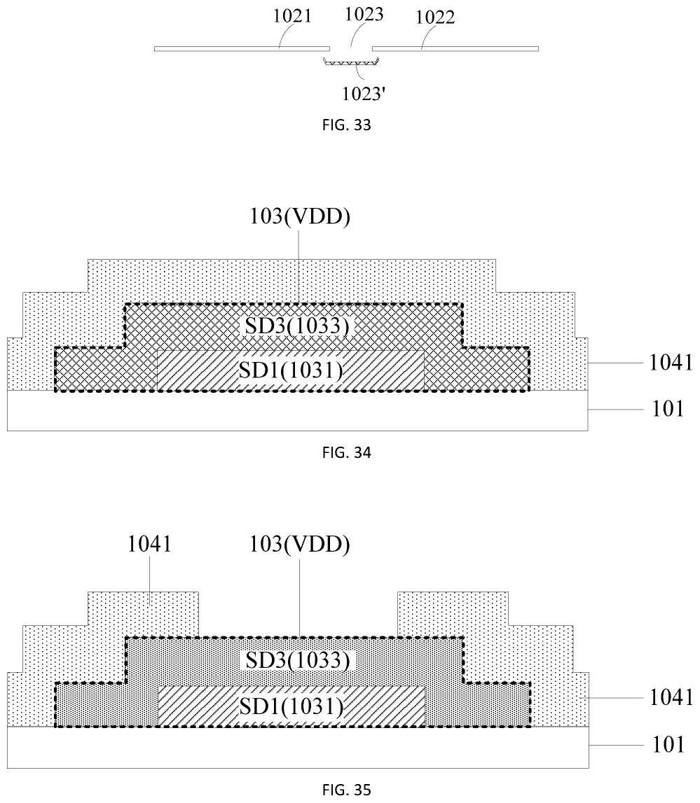

In some embodiments, the barrier dam 102 is discontinuous in the non-display area, that is, some positions of the barrier dam 102 is provided with gaps 1023 in the non-display area. As shown in FIG. 33, the barrier dam 102 includes a first barrier segment 1021 and a second barrier segment 1022 which are arranged at intervals, and the gap 1023 is formed between the first barrier segment 1021 and the second barrier segment 1022. The display substrate further includes a buffer portion 1023′ located at a side of the first barrier segment 1021 away from the display area AA, and the gap 1023 between the first barrier segment 1021 and the second barrier segment 1022 is opposite to the buffer portion 1023′. When the organic material flows out through the gap 1023 between the first barrier segment 1021 and the second barrier segment 1022, its speed is relatively fast. After flowing out from the gap 1023, the organic material bypasses the buffer part 1023′ and flows out from both sides of the buffer part 1023′, and the buffer part 1023′ can slow down the speed of the organic material overflowing outward. FIG. 33 only shows a partial structure of the barrier dam 102, the barrier dam 102 can form gaps 1023 at multiple places, and each gap 1023 may be provided with a buffer portion 1023′ on the side away from the display area AA.

Further, as shown in FIG. 33, the two ends of the buffer portion 1023′ are bent towards the display area AA to further slow down the speed of the organic material overflowing outward. The length of the buffer portion 1023′ may be greater than the size of the gap 1023 between the first barrier segment 1021 and the second barrier segment 1022, so as to more effectively slow down the overflow of organic materials. The buffer portion 1023′ can be in a wave shape, a straight line shape, a folded line shape, an arc shape, etc.

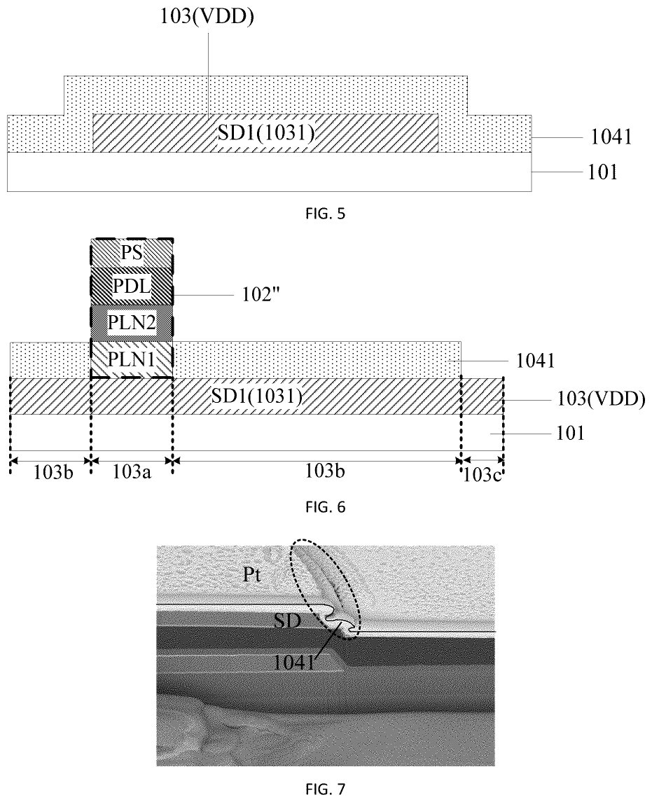

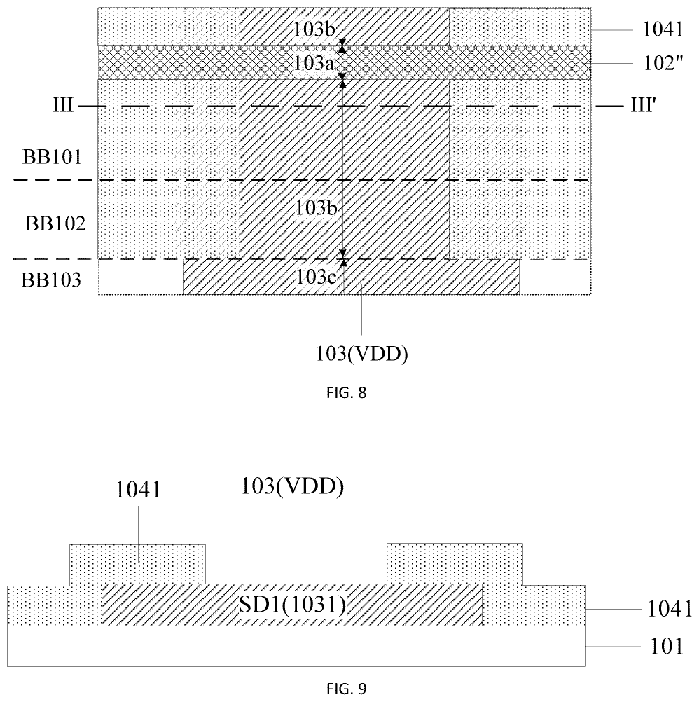

In some embodiments, in the above display substrate provided by the embodiments of the present disclosure, as shown in FIG. 4 and FIG. 5, the protection structure 1041 can completely cover the second segment 103b; or, as shown in FIG. 8 and FIG. 9, the protection structure 1041 may cover an edge(s) of the second segment 103b and expose the remaining area of the second segment 103b. In FIG. 4, FIG. 5, FIG. 8 and FIG. 9, the protection structure 1041 covers the edge(s) of the second segment 103b, so as to effectively prevent the side corrosion of the second segment 103b. Moreover, because the anode conductive layer 104 in the related art is a laminated structure composed of indium tin oxide/silver/indium tin oxide (ITO/Ag/ITO), and the resistance value of indium tin oxide is relatively large, so the larger an area of the second segment 103b covered by the protection structure 1041 located in the anode conductive layer 104 is, the greater the overall resistance of the second segment 103b and the protection structure 1041 is, and a larger resistance will cause loss of the power signal during transmission. Therefore, when the protection structure 1041 only covers the edge(s) of the second segment 103b and exposes the remaining area of the second segment 103b, the area covered by the protection structure 1041 can be effectively reduced, thereby facilitating the reduction of overall resistance between the second segment 103b and the protection structure 1041 and ensuring the authenticity of the power signal.

In some embodiments, the above-mentioned display substrate provided by the embodiments of the present disclosure, as shown in FIG. 5 and FIG. 9, further includes a first source-drain metal layer (SD1) disposed between the base substrate 101 and the anode conductive layer 104, the power line 103 may include a first sub-power line 1031 located in the first source-drain metal layer (SD1). By arranging the first sub-power line 1031 in the first source-drain metal layer (SD1), the fabrication of the first sub-power line 1031 is completed while making related structures (such as the source/drain of the transistor) in the first source-drain metal layer (SD1), thus avoiding the need to set up the film layer of the first sub-power line 1031 separately, reducing the number of film layers, and favoring the thin and lightweight design of the product. Optionally, the first source-drain metal layer (SD1) may be a laminated structure composed of titanium/aluminum/titanium (Ti/Al/Ti).

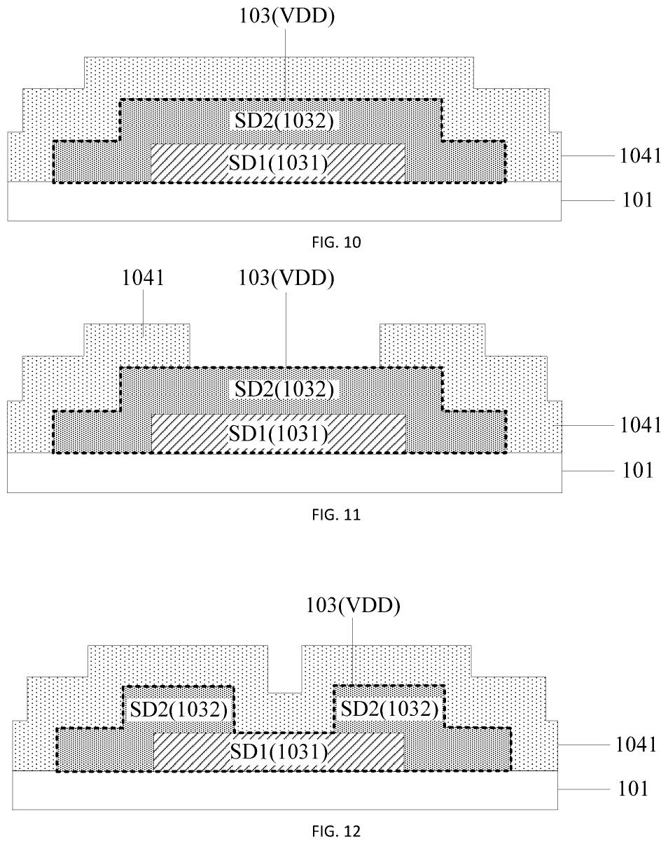

In some embodiments, the above-mentioned display substrate provided by the embodiments of the present disclosure, as shown in FIG. 10 to FIG. 13, may further include a second source-drain metal layer (SD2); the power line 103 may also include a second sub-power line 1032 located in the second source-drain metal layer (SD2), and the second sub-power line 1032 at least covers at least part of an edge(s) of the first sub-power line 1031. The power line 103 adopts a double-layer structure of the first sub-power line 1031 and the second sub-power line 1032, which is beneficial to reduce the overall resistance of the power line 103 and ensure the authenticity of the power signal. Optionally, the second source-drain metal layer (SD2) may be a laminated structure composed of titanium/aluminum/titanium (Ti/Al/Ti).

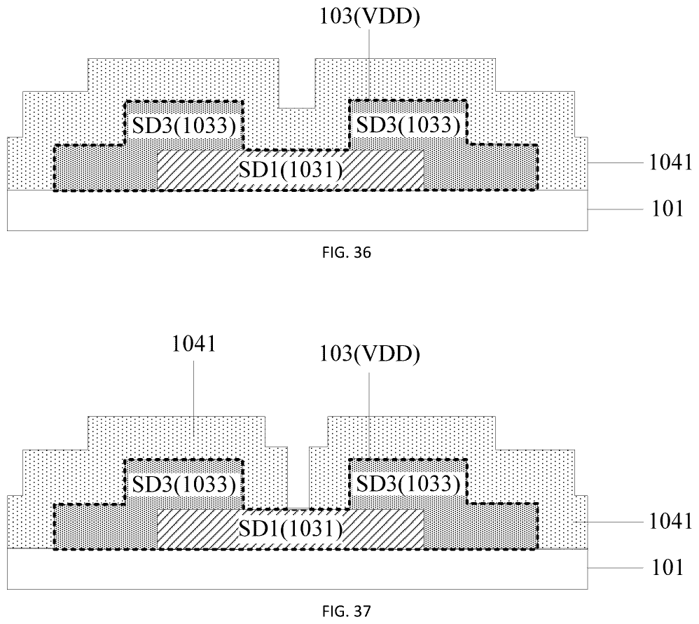

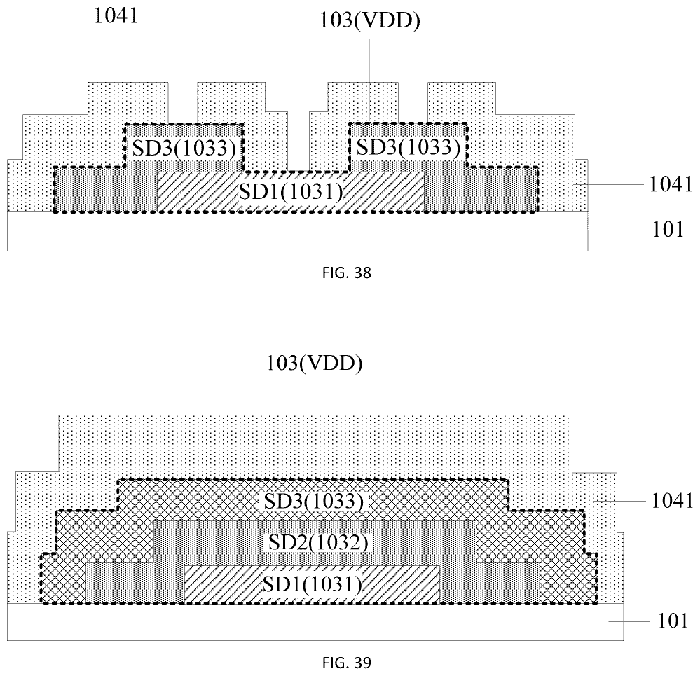

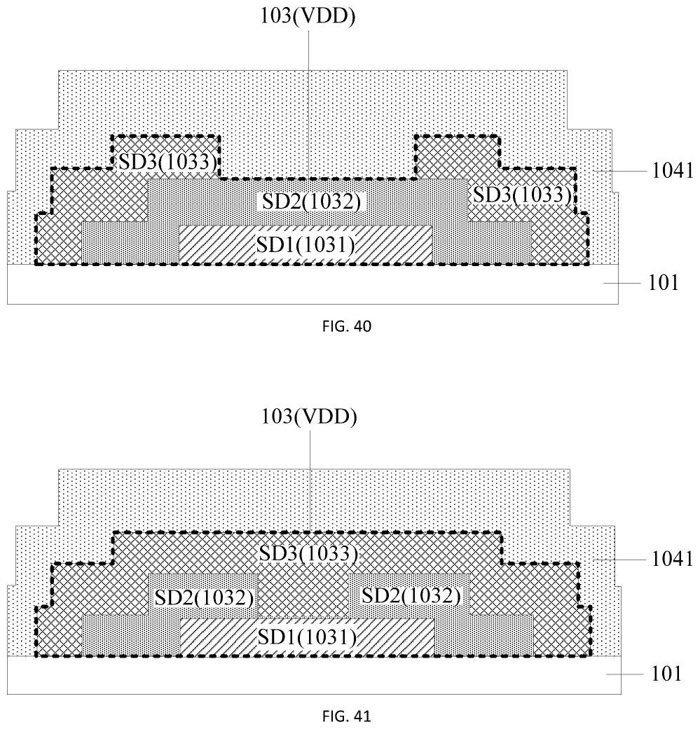

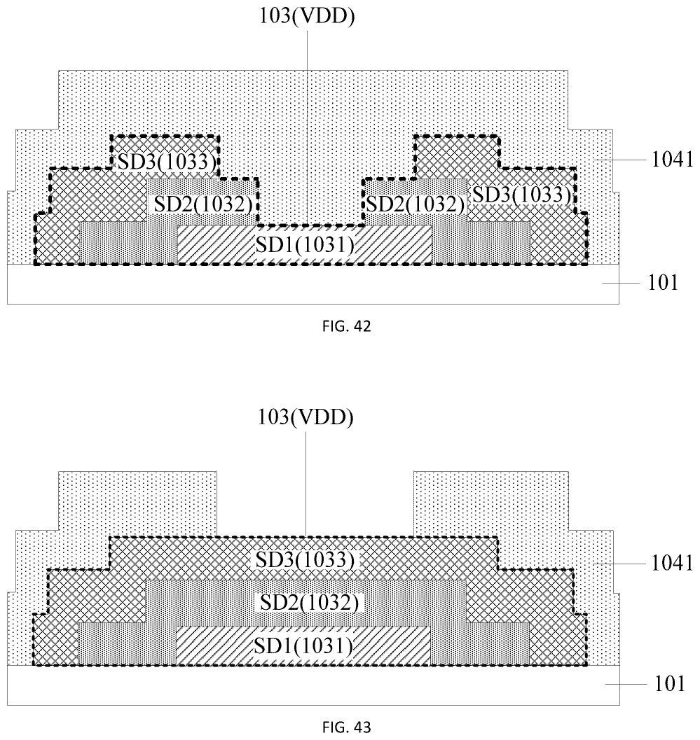

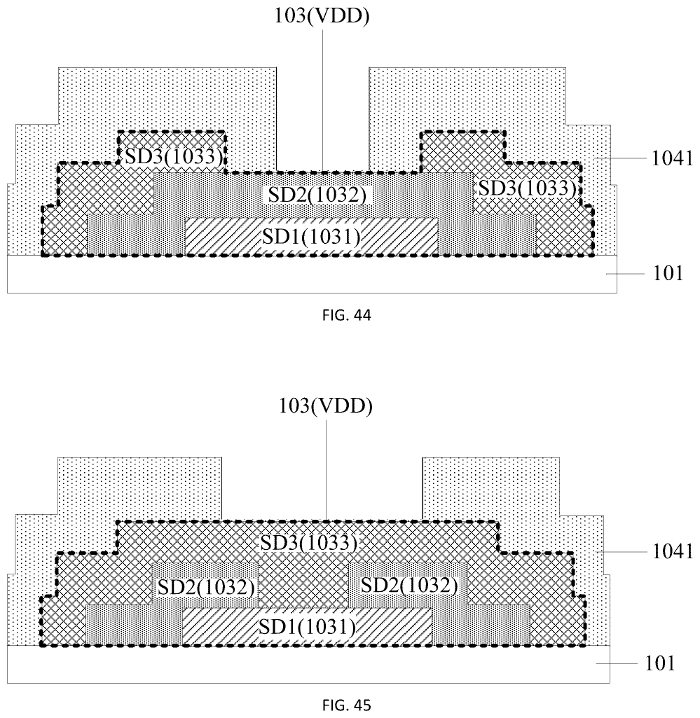

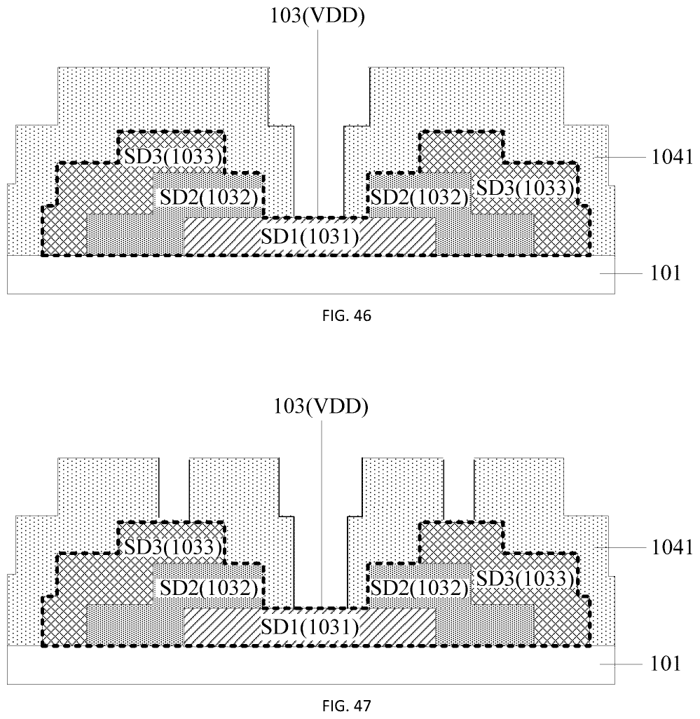

Further, in some embodiments, as shown in FIG. 34 to FIG. 47, it may further include a third source-drain metal layer (SD3) located between the second source-drain metal layer (SD2) and the anode conductive layer 104; the power line 103 may further include a third sub-power line 1033 located at the third source-drain metal layer (SD3), the third sub-power line 1033 at least covers at least part of the edge(s) of the first sub-power line 1031, for example, the third sub-power line 1033 covers at least the edge(s) of the first sub-power line 1031. The power line 103 adopts a double-layer structure of the first sub-power line 1031 and the third sub-power line 1033 (as shown in FIG. 34 to FIG. 38), or adopts a three-layer structure of the first sub-power line 1031, the second sub-power line 1032 and the third sub-power line 1033 (as shown in FIG. 39 to FIG. 47), which is beneficial to reduce the overall resistance of the power line 103 and ensure the authenticity of the power signal. In some embodiments, in the above-mentioned display substrate provided by the embodiments of the present disclosure, as shown in FIG. 10 and FIG. 11, the second sub-power line 1032 can completely cover the first sub-power line 1031; alternatively, as shown in FIG. 12 to FIG. 15, the second sub-power line 1032 may cover the edge(s) of the first sub-power line 1031 and expose the remaining area of the first sub-power line 1031. Both of these covering methods can effectively reduce the overall resistance of the power line 103 and ensure the authenticity of the power signal. Of course, the second sub-power line 1032 may also only cover a position where the second segment 103b of the first sub-power line 1031 is located, and disconnect at a position where the first segment 103a of the first sub-power line 1031, which is not limited here.

In some embodiments, in the above-mentioned display substrate provided by the embodiments of the present disclosure, as shown in FIG. 5 and FIG. 9, when the power line 103 is only composed of the first sub-power line, the protection structure 1041 at least cover an edge(s) of the second segment 103b of the first sub-power line. For example, in FIG. 5, the protection structure 1041 completely covers the edge(s) of the second sub-section 103b of the first sub-power line 1031; for another example, the protection structure 1041 covers the edge(s) of the first sub-power line 1031 and exposes the remaining area of the first sub-power line 1031.

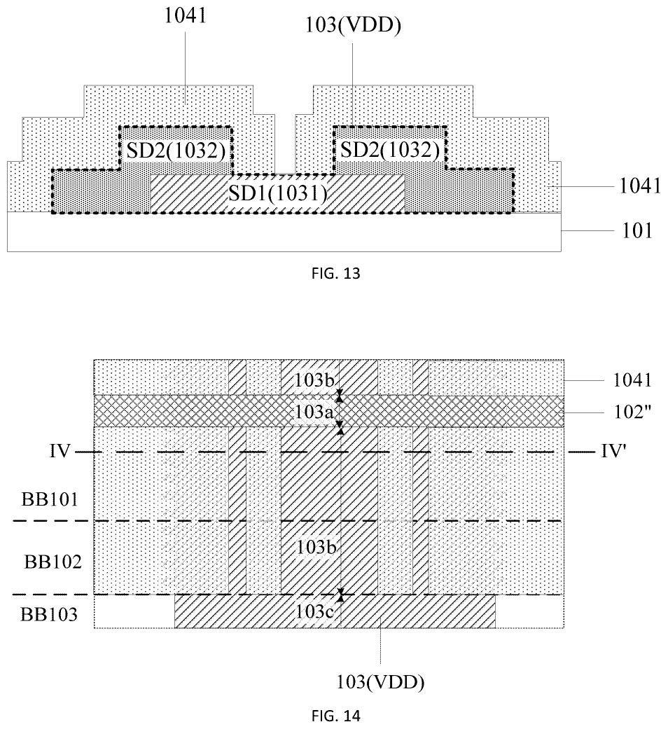

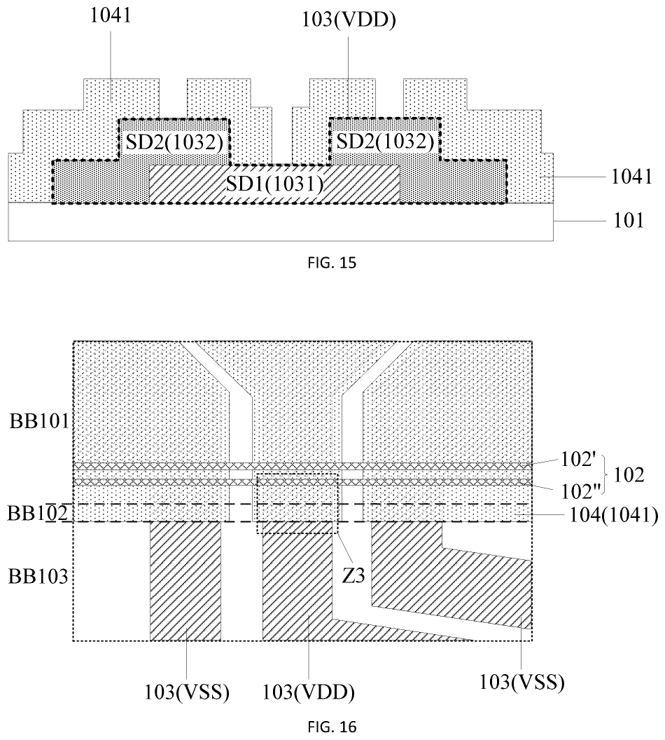

As shown in FIG. 10 to FIG. 15, when the power line 103 is composed of the first sub-power line 1031 and the second sub-power line 1032, the second sub-power line 1032 covers at least the edge(s) of the first sub-power line 1031. In order to prevent the etching solution used for the anode from corroding the side of the power line 103, and an edge(s) of the second sub-power line 1032 needs to be protected, that is, the protection structure 1041 needs to at least cover the edge(s) of the second sub-power line 1032. Specifically, in FIG. 10 and FIG. 11, the second sub-power line 1032 completely covers the edge(s) of the first sub-power line 1031; in FIG. 12 to FIG. 13, the second sub-power line 1032 covers the edge(s) of the first sub-power line 1031 and exposes the remaining area of the first sub-power line 1031. Correspondingly, in FIG. 10 and FIG. 12, the protection structure 1041 completely covers an edge(s) of the second segments 103b of the first sub-power line 1031 and the second sub-power line 1032; in FIG. 11, FIG. 14 and FIG. 15, the protection structure 1041 covers the edge(s) of the second sub-section 103b of the second sub-power line 1032 and exposes the remaining area of the second sub-section 103b of the second sub-power line 1032, and in FIGS. 14 and 15, a part of an non-edge area of the second sub-section 103b of the first sub-power line 1031 is also exposed by the protection structure 1041. In FIG. 13, the protection structure 1041 completely covers the edge(s) of the second segment 103b of the second sub-power line 1032 and exposes a part of the non-edge area of the second segment 103b of the first sub-power line 1031. When the power line 103 is composed of the first sub-power line 1031 and the third sub-power line 1033, reference may be made to the relevant content when the power line 103 is composed of the first sub-power line 1031 and the second sub-power line 1032, and details will not be repeated here. When the power line 103 is composed of the first sub-power line 1031, the second sub-power line 1032 and the third sub- power line 1033, as shown in FIG. 39 to FIG. 42, the protection structure 1041 may completely cover the first sub-power line 1031, the second sub-power line 1032 and the third sub-power line 1033; or, as shown in FIG. 43 to FIG. 47, the protection structure 1041 may completely cover an edge(s) of the third sub-power line 1033 and an edge(s) of the second sub-power 1032 that is not covered by the third sub-power line 1033.

In some embodiments, in the above display substrate provided by the embodiments of the present disclosure, as shown in FIG. 16 to FIG. 18, the protection structure 1041 may also at least cover at least a portion of an edge(s) of the first segment 103a, optionally, the protection structure 1041 at least cover the edge(s) of the first segment 103a. For example, the protection structure 1041 may also completely cover the edge(s) of the first segment 103a, or the protection structure 1041 covers the edge(s) of the first segment 103a and exposes the remaining area of the first segment 103a, that is to say, the protection structure 1041 may be continuously arranged at least at the edges of the first segment 103a and the second segment 103b. The continuous arrangement of the protection structure 1041 is beneficial to the fabrication of the protection structure 1041 on the one hand; on the other hand, since the first segment 103a and the barrier dam 102 are stacked, it is equivalent to adding a protection structure 1041 between the barrier dam 102 and the first segment 103a, so that the height of the barrier dam 102 is increased due to the existence of the protection structure 1041, thereby better blocking the intrusion of water and oxygen, and effectively improving the packaging reliability.

In some embodiments, in the above display substrate provided by the embodiments of the present disclosure, as shown in FIG. 2 and FIG. 16, the power line 103 may include a first-level power line VDD and a second-level power line VSS, here, the protection structure 1041 is disconnected at a gap between the first-level power line VDD and the second-level power line VSS, so as to ensure the independent transmission of the first-level power signal and the second-level power signal, and avoid the two interfering with each other.

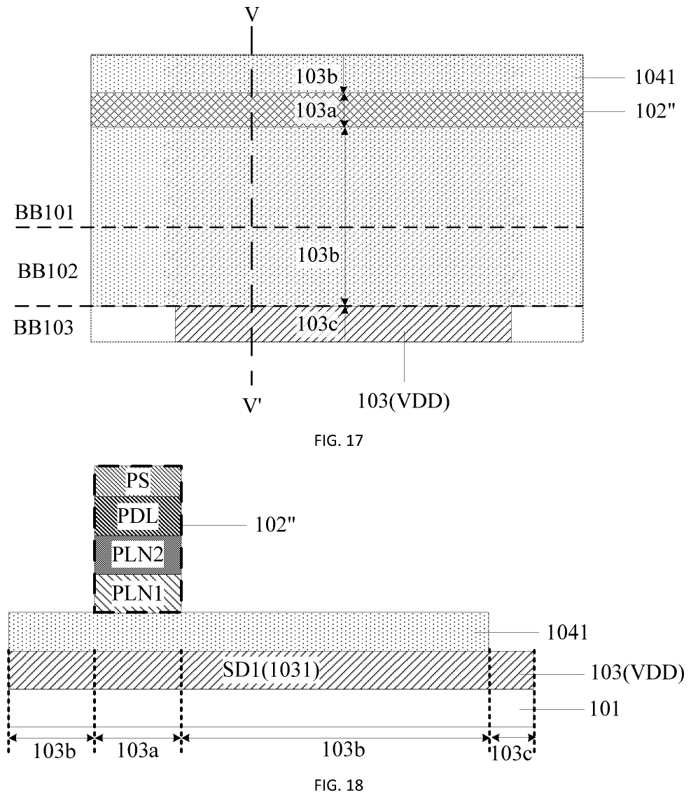

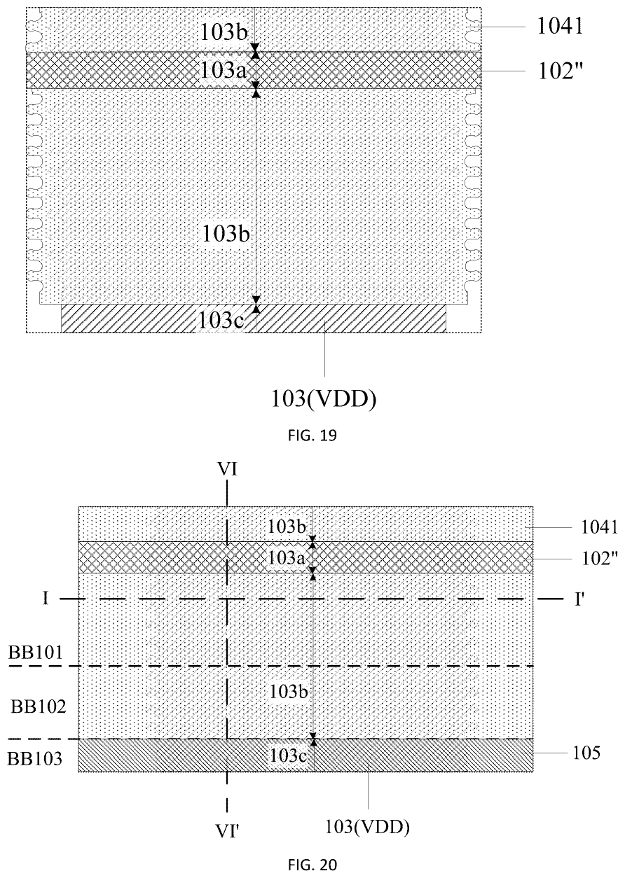

In some embodiments, in the above-mentioned display substrate provided by the embodiments of the present disclosure, as shown in FIG. 4, FIG. 8, FIG. 14, FIG. 17 and FIG. 19, an edge(s) of the first segment 103a and/or an edge(s) of the second segment 103b may include an irregular structure (for example, a wavy structure), so as to prolong the intrusion path of water and oxygen and improve packaging reliability.

In some embodiments, in the above-mentioned display substrate provided by the embodiments of the present disclosure, as shown in FIG. 19, in order to obtain a better covering effect, a shape of an edge(s) of the protection structure 1041 may be roughly the same as a shape of the edge(s) of the second segment 103b (that is, they may be exactly the same, or there may be errors caused by manufacturing processes, etc.). Certainly, as shown in FIG. 4, FIG. 8, FIG. 14 and FIG. 17, the shape the edge(s) of the protection structure 1041 may also be rectilinear, which is not limited here.

In some embodiments, in the above display substrate provided by the embodiments of the present disclosure, as shown in FIG. 2, FIG. 4, FIG. 8, FIG. 14 and FIG. 17, the non-display area BB may include: a first non-display area BB1 for banding with a chip, the first non-display area BB1 includes an encapsulation area BB101 and a water-oxygen isolation area BB102 arranged in sequence in a direction away from the display area AA. The barrier dam 102 in the first non-display area BB1 is located in the encapsulation area BB101 and the second segment 103b is located in the encapsulation area BB101 and the water-oxygen isolation area BB102 to better prevent water and oxygen intrusion and effectively improve packaging reliability.

In some embodiments, in the above display substrate provided by the embodiments of the present disclosure, as shown in FIG. 2, FIG. 4, FIG. 8, FIG. 14, FIG. 17 and FIG. 20, the first non-display area may further include a fan-out area BB103 and binding area BB104, here, the fan-out area BB103 connects with the water-oxygen isolation area BB102 and the binding area BB104. The power line 103 may also include a third segment 103c located in the fan-out area BB103, and the third segment 103c and the second segment 103b are integrated to bind to the chip after extending the power line 103 to the binding area BB104, so as to realize that the chip provides a power signal for the power line 103.

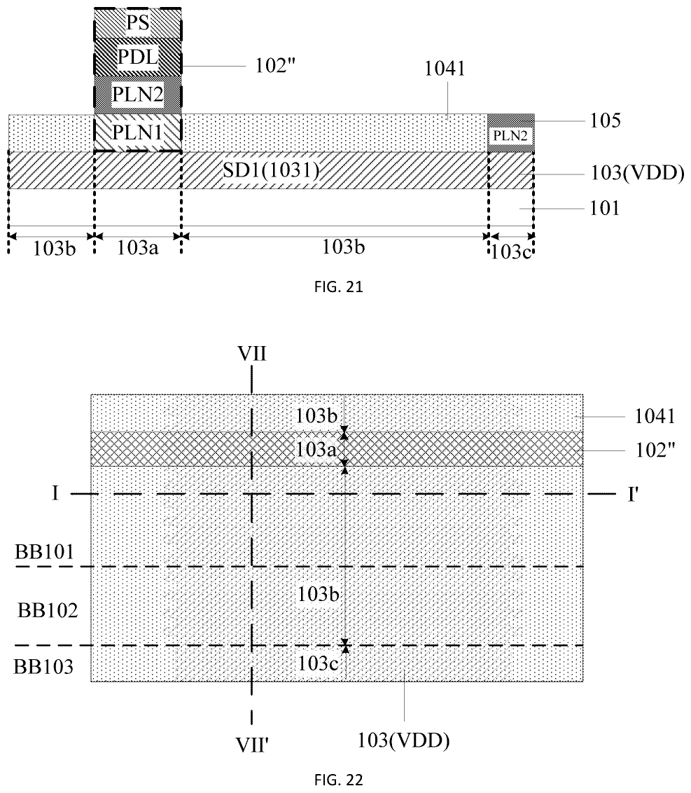

In some embodiments, the above-mentioned display substrate provided by the embodiments of the present disclosure, as shown in FIG. 20 and FIG. 21, may further include a planarization layer 105 (namely, the above-mentioned second planarization layer PLN2), the planarization layer 105 is disposed between a layer where the power line 103 is located and the anode conductive layer 104, and the planarization layer 105 is provided on the entire surface of the fan-out area BB103, so as to protect the third segment 103c through the planarization layer 105 and prevent the etching solution used for the anode from causing the side corrosion on the third segment 103c.

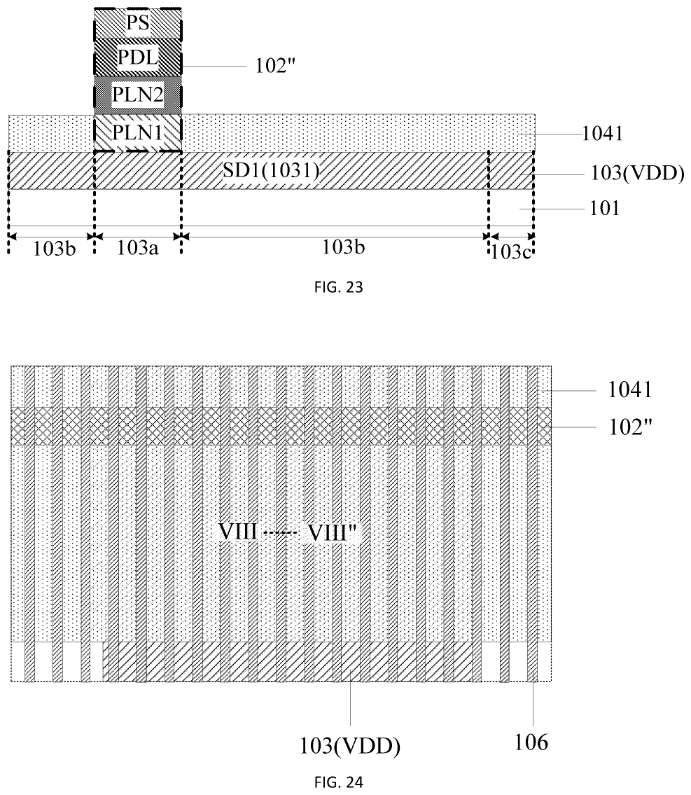

In some embodiments, in the above-mentioned display substrate provided by the embodiments of the present disclosure, as shown in FIG. 22 and FIG. 23, the protection structure 1041 may also at least cover an edge(s) of the third segment 103c, for example, the protection structure 1041 completely covers the edge(s) of the third segment 103c, or the protection structure 1041 covers the edge(s) of the third segment 103c and exposes the remaining area of the third segment 103c, so that the third segment 103c is protected by the protection structure 1041, to prevent the etching solution used for the anode from causing the side corrosion on the third segment 103c.

In some embodiments, the above-mentioned display substrate provided by the embodiments of the present disclosure, as shown in FIG. 2 and FIG. 24, may also include a plurality of touch lines 106 located in the non-display area BB, and the plurality of touch lines 106 is located at a side, away from the base substrate 101, of a layer where the barrier bam 102 is located. An orthographic projection of at least part of the touch lines 106 on the base substrate 101 and an orthographic projection of the power line 103 on the base substrate 101 overlap with each other. The protection structure is at least partially located in the overlapping area.

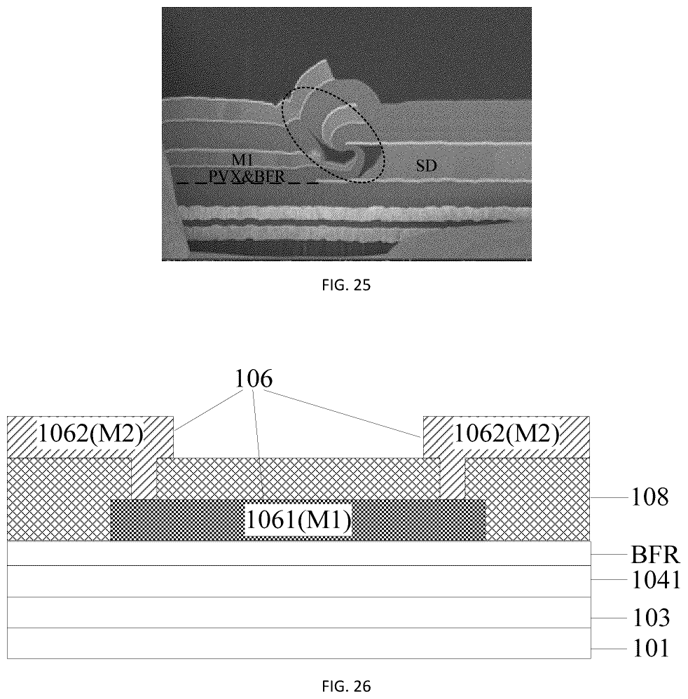

As shown in FIG. 25, the power line 103 (SD) in the related art suffers an undercut, and when a buffer layer (BFR) is subsequently deposited, the buffer layer (BFR) will be broken at a position where the side corrosion exists (as shown in the dotted line box in the figure), resulting in a short between the touch lines 106 of the bridging layer (M1) and the power line 103 (SD) after the coating of the bridging layer (M1) on the buffer layer is completed. However, in the present disclosure, the protection structure 1041 is used to cover at least the edge(s) of the second segment 103b to avoid the side corrosion of the power line 103, thus effectively preventing the short between the touch lines 106 and the power line 103.

In some embodiments, in the above display substrate provided by the embodiments of the present disclosure, as shown in FIG. 2, at least some of the touch lines 106 include a conductive winding part C, so that the resistances of the touch lines 106 are approximately the same, that is, a resistance difference of the touch lines 106 is within an acceptable range (for example, ±10%), and an orthographic projection of the conductive winding part C on the base substrate 101 is located between the orthographic projection of the barrier dam 102 on the base substrate 101 and display area AA. By winding at least part of the touch lines 106, the resistance of each touch line 106 may be roughly the same to ensure that the signal delay (RC delay) effect of each touch line 106 is basically the same, so that the signals loaded on touch electrodes 107 electrically connected with the touch lines 106 are substantially the same. Therefore, the influence of the large difference in the resistance of touch lines 106 on touch control can be improved, which is beneficial to improving touch performance. Moreover, the conductive winding part C of the present disclosure is disposed in the area between the barrier dam 102 and the display area AA, and the space inside the barrier dam 102 can be reasonably utilized, so that there is no need to increase the width of the non-display area BB.

In some embodiments, the above-mentioned display substrate provided by the embodiments of the present disclosure, as shown in FIG. 24 and FIG. 26, may further include a bridging layer (M1) and a touch layer (M2) that are insulated from each other, and the bridging layer (M1) is disposed between the layer where the barrier dam 102 is located and the touch layer (M2); the touch lines each 106 includes a first sub-touch line 1061 and a second sub-touch line 1062 electrically connected with each other, where the first sub-touch line 1061 is located in the bridging layer (M1), and the second sub-touch line 1062 is located in the touch layer (M2). This double-layer wiring method of the touch lines 106 can not only effectively reduce the resistance of the touch lines 106, but also ensure the continuity of the touch lines 106 through the other layer of lines after one layer of lines is partially broken, thereby effectively solving the problem that a single layer of lines is broken and easily leads to touch failure. In some embodiments, a through hole may be provided in an insulating layer between the bridging layer (M1) and the touch layer (M2) at a preset distance (for example, 100 μm) in the non-display area BB, so that the two layers of wiring of the touch line 106 are electrically connected through the through hole.

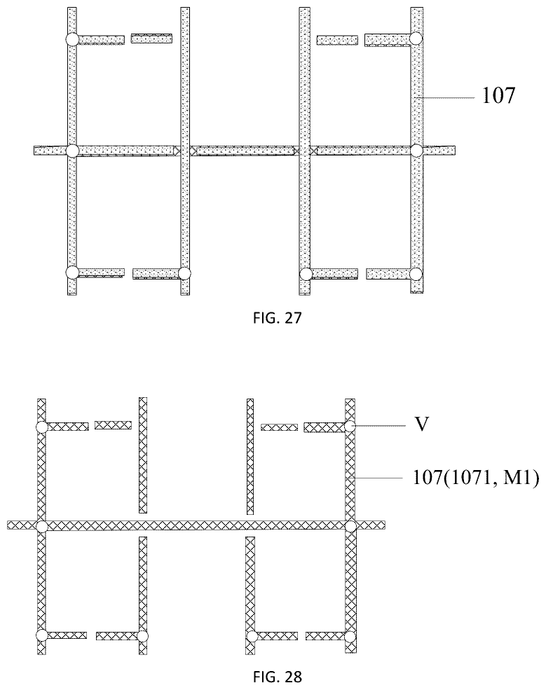

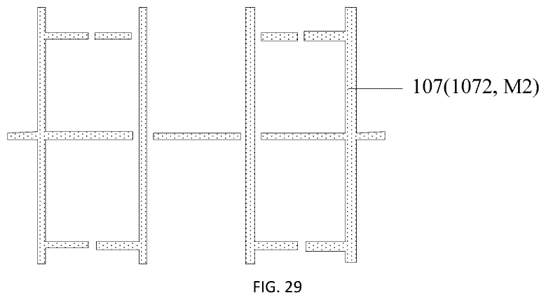

In some embodiments, the above-mentioned display substrate provided by the embodiments of the present disclosure, as shown in FIG. 2, FIG. 27 to FIG. 29, may further includes a plurality of touch electrodes 107 located in the display area AA, and the touch electrodes 107 are electrically connected with the touch lines 106. The touch electrodes 107 include first sub-touch electrodes 1071 and second sub-touch electrodes 1072 electrically connected with each other, where the first sub-touch electrodes 1071 are located in the bridging layer (M1), and the second sub-touch electrodes 1072 are located in the touch layer (M2). The double-layer arrangement of the touch electrodes 107 can not only effectively reduce the resistance of the touch electrodes 107, but also make it possible to ensure continuity of the touch electrodes 107 through the other one of sub-touch electrodes after one of the sub-touch electrodes 107 is partially broken, thereby effectively solving the problem that the touch electrodes 107 with a single-layer structure is broken and easily leads to touch failure. In some embodiments, a through hole V may be provided in the insulating layer between the bridging layer (M1) and the touch layer (M2) at a preset distance (for example, 100 μm) in the display area AA, so that the first sub-touch electrodes 1071 and the second sub-touch electrodes 1072 are electrically connected through the through the through hole V. In addition, because the present disclosure can realize the touch function by using the touch layer (M2) and the bridging layer (M1) in the display substrate, there is no need for an external touch module (TSP), so that the thickness of the display substrate can be reduced, which is conducive to folding; at the same time, there is no fit tolerance, which can reduce a width of a border.

In some embodiments, in the above-mentioned display substrate provided by the embodiments of the present disclosure, as shown in FIG. 28, the plurality of through holes V connecting first sub-touch electrodes 1071 and second sub-touch electrodes 1072 may be evenly distributed in the display area AA to improve the visible afterimage of the through holes V and achieve the effect of eliminating the image on the through holes V.

In some embodiments, in the above display substrate provided by the embodiments of the present disclosure, as shown in FIG. 2, the plurality of touch electrodes 107 may include a plurality of first touch electrodes 107′ extending along the first direction Y, and a plurality of second touch electrodes 107″ extending along the second direction X; the plurality of touch lines 106 includes a plurality of first touch lines 106′ and a plurality of second touch lines 106″. The first touch electrodes 107′ are electrically connected with the first touch lines 106′, and the second touch electrodes 107″ is electrically connected with the second touch lines 106″.

Optionally, in the above display substrate provided by the embodiments of the present disclosure, the first touch electrodes 107′ may be touch drive electrodes (Tx), and the first touch lines 106′ are touch drive lines accordingly; the second touch electrodes 107″ may be touch sensing electrodes (Rx), and the second touch lines 106″ are touch sensing lines accordingly. Or, the first touch electrodes 107′ are touch sensing electrodes, and the first touch line 106′ are touch sensing lines accordingly; the second touch electrodes 107″ are touch drive electrodes, and the second touch lines 106″ are touch drive lines accordingly.

It can be seen from FIG. 2 that the first touch electrodes 107′ extending along the first direction Y are disconnected by the second touch electrodes 107″ extending along the second direction X in the same layer. Therefore, in order to ensure the continuity of the first touch electrodes 107′, the disconnected second touch electrodes 107″ may be connected by using the bridging portion BD of the bridging layer (M1).

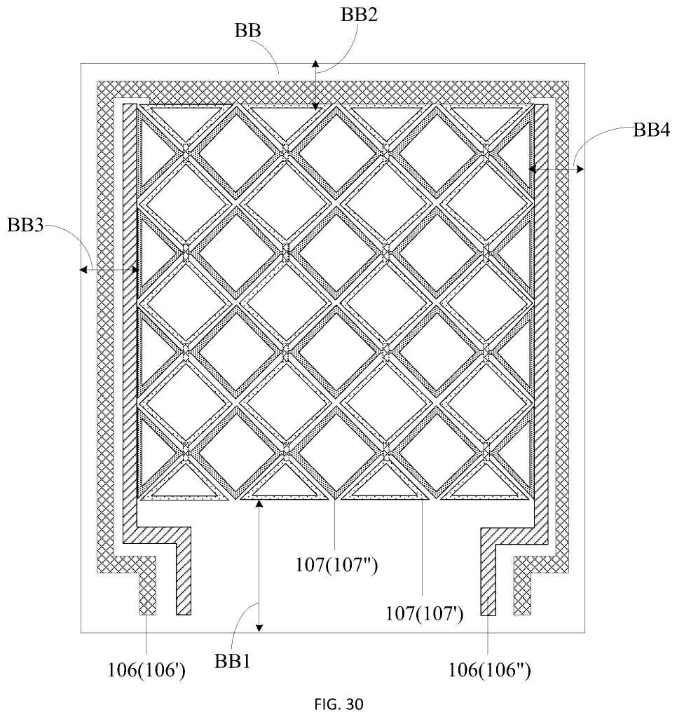

In some embodiments, in the above display substrate provided by the embodiments of the present disclosure, as shown in FIG. 2 and FIG. 30, the non-display area BB may include a first non-display area BB1 and a second non-display area BB2 disposed opposite to each other, and a third non-display area BB3 and a fourth non-display area BB4 disposed opposite to each other. Here, the first non-display area BB1 is a first non-display area BB1 binding with the chip, and the third non-display area BB3 and the fourth non-display area BB1 are connected with the first non-display area BB1 and the second non-display area BB2, respectively; when the size of the display substrate is large (for example, the display substrate is a notebook, etc.), more touch electrodes 107 need to be provided, correspondingly more touch lines 106 are needed. In order to ensure the narrow bezel effect, as shown in FIG. 30, it can be set that: a plurality of second touch lines 106″ extend from the third non-display area BB3 and the fourth non-display area BB4, and then are folded to extend to the first non-display area BB1; some of the first touch lines 106′ pass sequentially through the second non-display area BB2 and the third non-display area BB3 and are folded to extent to the first non-display area BB1, and the remaining first touch lines 106′ extend sequentially through the second non-display area BB2 and the fourth non-display area BB4 and are folded to extend to the first non-display area BB1, and in the third non-display area BB3 and the fourth non-display area BB4, the first touch lines 106′ are located at a side of the second touch line 106″ away from the display area AA. When the size of the display substrate is small (for example, the display substrate is a mobile phone, etc.), fewer touch electrodes 107 and correspondingly fewer touch lines 106 are required. In order to ensure the narrow bezel effect, as shown in FIG. 2, the plurality of second touch lines 106″ may extend from the fourth non-display area BB4 and be folded to extend to the first non-display area BB1; some of the first touch lines 106′ may pass through the second non-display area BB2 and the third non-display area BB3 in sequence and be folded to extend to the first non-display area BB1, and the remaining first touch lines 106′ may be located in the first non-display area BB1.

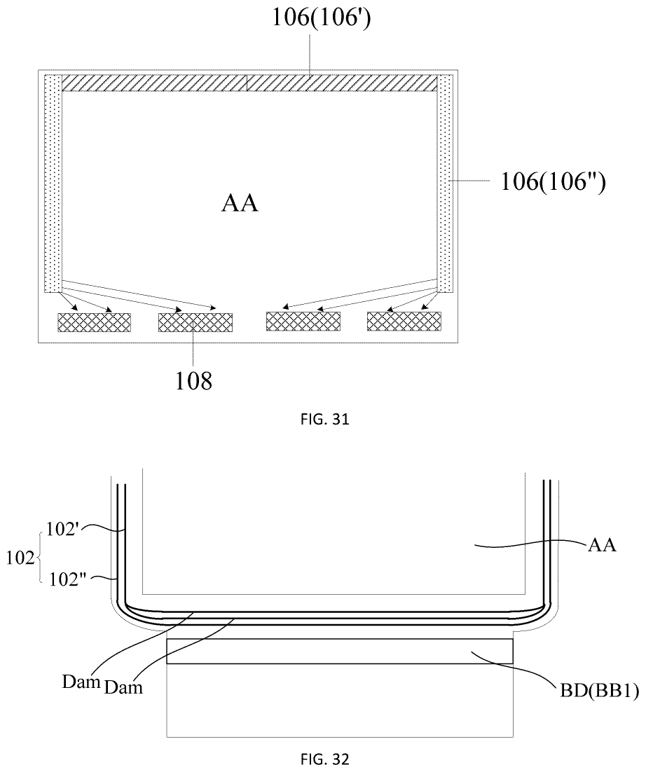

In some embodiments, the above-mentioned display substrate provided by the embodiments of the present disclosure, as shown in FIG. 31, may further include at least one touch chip 108, and a plurality of touch lines 106 are bound to the touch chips 108. The touch chip 108 can be a chip-on-film (COF).

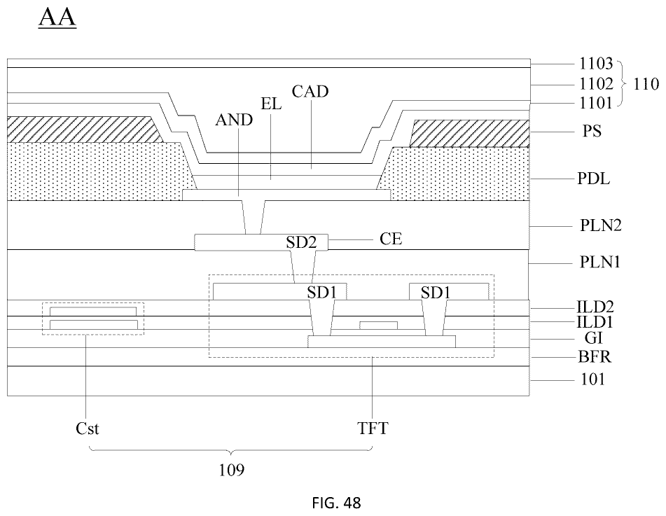

In some embodiments, as shown in FIG. 48, a driving circuit layer is disposed on the base substrate 101, and a pixel circuit 109 of a sub-pixel is arranged in the driving circuit layer, and the pixel circuit 109 is configured to drive the sub-pixel to emit light. The pixel circuit includes a transistor TFT, and may also include a capacitor Cst. For example, the pixel circuit 109 may be a 1T pixel circuit, a 2T1C pixel circuit, a 3T1C pixel circuit, a 4T1C pixel circuit, a 5T1C pixel circuit, a 6T1C pixel circuit or a 7T1C pixel circuit.

In some embodiments, as shown in FIG. 48, a light emitting layer EL is disposed at a side of the driving circuit layer 109 away from the base substrate 101. The light emitting layer EL may include a red sub-pixel R, a green sub-pixel G and a blue sub-pixel B, but not limited thereto. The red sub-pixel R is used to emit red light, the green sub-pixel G is used to emit green light, and the blue sub-pixel B is used to emit blue light.

In some embodiments, the light emitting layer EL is an organic light emitting layer. The red sub-pixel R, the green sub-pixel G and the blue sub-pixel B are all organic light emitting diode (OLED) sub-pixels.

In some embodiments, as shown in FIG. 48, an encapsulation layer 110 is disposed at a side of the light-emitting layer EL away from the base substrate 101 to prevent water and oxygen from corroding the light-emitting layer. The encapsulation layer 110 includes a first inorganic encapsulation layer 1101, an organic encapsulation layer 1102, and a second inorganic encapsulation layer 1103. The first inorganic encapsulation layer 1101 is disposed at the side of the light-emitting layer EL away from the substrate 101, and the organic encapsulation layer 1102 is disposed at a side of the first inorganic encapsulation layer 1101 away from the base substrate 101, and the second inorganic encapsulation layer 1103 is disposed at a side of the organic encapsulation layer 1102 away from the base substrate 101. The organic encapsulation layer 1102 may be formed using an inkjet printing (IJP) process. In addition, the display substrate can also include a cathode CAD, a gate insulating layer GI, a first interlayer dielectric layer ILD1 and a second interlayer dielectric layer ILD2, etc., and other essential components of the display substrate are all understood by those of ordinary skill in the art, which will not be repeated herein, nor should it be used as a limitation to the present disclosure.

Based on the same inventive concept, the present disclosure also provides a display apparatus, including the above-mentioned display substrate provided by the embodiments of the present disclosure, and the display substrate may be a display substrate such as an OLED or a QLED. Since the problem-solving principle of the display apparatus is similar to the problem-solving principle of the above-mentioned display substrate, the implementation of the display apparatus can refer to the above-mentioned embodiments of the display substrate, which will not be repeated herein.

In some embodiments, the above-mentioned display apparatus provided by the embodiments of the present disclosure may be any product or assembly unit with a display function, e.g., a mobile phone, a tablet computer, a television, a monitor, a notebook computer, a digital photo frame, a navigator, a smart watch, a fitness wristband, a personal digital assistant, etc. The display apparatus provided by the embodiments of the present disclosure may also include but not limited to: elements, e.g., a radio frequency unit, a network module, an audio output unit, an input unit, a sensor, a display unit, a user input unit, an interface unit, a memory, a processor, and a power supply. Those skilled in the art can understand that the composition of the above display apparatus does not constitute a limitation on the display apparatus, and the display apparatus may include more or less of the above components, or combine certain components, or arrange different components.

Although the present disclosure has described preferred embodiments, it should be understood that those skilled in the art can make various changes and modifications to the disclosed embodiments without departing from the spirit and scope of the disclosed embodiments. In this way, if these modifications and variations of the embodiments of the present disclosure fall within the scope of the claims of the present disclosure and their equivalent technologies, the present disclosure also intends to include these modifications and variations.

1-26. (canceled)

27. A display substrate, comprising:
a base substrate, comprising a display area and a non-display area arranged around the display area;
a barrier dam in the non-display area and at least partially disposed around the display area;
a power line in the non-display area on a side of the display area; wherein the power line comprises a first segment and a second segment integrally arranged, an orthographic projection of the first segment on the base substrate roughly coincides with an orthographic projection of the barrier dam on the base substrate, and an orthographic projection of the second segment on the base substrate does not overlap with the orthographic projection of the barrier dam on the base substrate; and
an anode conductive layer at a side, away from the base substrate, of a layer where the power line is located, wherein the anode conductive layer comprises a protection structure at least partially located in the non-display area, and the protection structure at least covers at least part of an edge of the second segment.

28. The display substrate according to claim 27, wherein the protection structure completely covers the second segment, or the protection structure covers the edge of the second segment and exposes remaining area of the second segment.

29. The display substrate according to claim 27, further comprising a first source-drain metal layer disposed between the base substrate and the anode conductive layer, and the power line comprises a first sub-power line located in the first source-drain metal layer.

30. The display substrate according to claim 29, further comprising a second source-drain metal layer disposed between the first source-drain metal layer and the anode conductive layer; and
the power line further comprises a second sub-power line located in the second source-drain metal layer, and the second sub-power line at least covers an edge of the first sub-power line.

31. The display substrate according to claim 30, wherein the second sub-power line completely covers the first sub-power line, or the second sub-power line covers the edge of the first sub-power line and exposes remaining area of the first sub-power line, or the protection structure at least covers at least part of the edge of the second segment of the second sub-power line.

32. The display substrate according to claim 27, wherein the protection structure further at least covers at least part of the edge of the first segment;
or
the power line comprises a first-level power line and a second-level power line, wherein the protection structure is disconnected at a gap between the first-level power line and the second-level power line.

33. The display substrate according to claim 27, wherein an edge of the first segment and/or an edge of the second segment comprise an irregular structure.

34. The display substrate according to claim 33, wherein a shape of an edge of the protection structure is roughly the same as a shape of an edge of the second segment.

35. The display substrate according to claim 27, wherein the non-display area comprises a first non-display area binding with a chip, wherein the first non-display area comprises an encapsulation area and a water-oxygen isolation area arranged in sequence in a direction away from the display area; and
the barrier dam in the first non-display area is in the encapsulation area, and the second segment is in the encapsulation area and the water-oxygen isolation area.

36. The display substrate according to claim 35, wherein the first non-display area further comprises a fan-out area and a binding area, wherein the fan-out area connects with the water-oxygen isolation area and the binding area; and
the power line further comprises a third segment located in the fan-out area, and the third segment is integrated with the second segment.

37. The display substrate according to claim 36, further comprising a planarization layer disposed between the layer where the power line is located and the anode conductive layer, and the planarization layer is provided on an entire surface of the fan-out area.

38. The display substrate according to claim 37, wherein the protection structure further at least covers at least part of an edge of the third segment.

39. The display substrate according to claim 27, further comprising a plurality of touch lines located in the non-display area, and the plurality of touch lines being located at a side, away from the base substrate, of a layer where the barrier dam is located; an orthographic projection of at least part of the touch lines on the base substrate and the orthographic projection of the power line on the base substrate overlap with each other, and the protection structure is at least partially located at an overlapping area.

40. The display substrate according to claim 39, wherein at least some of the touch lines comprise a conductive winding part, so that resistances of the touch lines are approximately the same, and an orthographic projection of the conductive winding part on the base substrate is located between the orthographic projection of the barrier dam on the base substrate and the display area.

41. The display substrate according to claim 40, further comprising a bridging layer and a touch layer insulated from each other, wherein the bridging layer is disposed between the layer where the barrier dam is located and the touch layer; and
the touch control line comprises a first sub-touch line and a second sub-touch line electrically connected with each other, wherein the first sub-touch line is located in the bridging layer, and the second sub-touch line is located in the touch layer.

42. The display substrate according to claim 41, further comprising a plurality of touch electrodes located in the display area; the touch electrodes are electrically connected with the touch lines; the touch electrodes comprise first sub-touch electrodes and second sub-touch electrodes electrically with each other, wherein the first sub-touch electrodes are located in the bridging layer, and the second sub-touch electrodes are located in the touch layer.

43. The display substrate according to claim 42, further comprising an insulating layer between the touch layer and the bridging layer; the insulating layer comprises a plurality of through holes, and the first sub-touch electrodes connect with the second sub-touch electrodes through the through holes, and the plurality of through holes are uniformly distributed in the display area.

44. The display substrate according to claim 42, wherein the plurality of touch electrodes comprises a plurality of first touch electrodes extending along a first direction, and a plurality of second touch electrodes extending along a second direction; the plurality of touch lines comprise a plurality of first touch lines and a plurality of second touch lines; wherein the first touch electrodes are electrically connected with the first touch lines, and the second touch electrodes are electrically connected with the second touch lines.

45. The display substrate according to claim 44, wherein the non-display area comprises a first non-display area and a second non-display area opposite to each other, and a third non-display area and a fourth non-display area opposite to each other; wherein the first non-display area is a first non-display area binding with the chip, the third non-display area and the fourth non-display area are connected with the first non-display area and the second non-display area, respectively;
the plurality of second touch lines extend from the third non-display area and the fourth non-display area, and then are folded to extend toward the first non-display area; and
some of the first touch lines pass through the second non-display area and the third non-display area in sequence and are folded to extend toward the first non-display area, and remaining first touch lines pass through the second non-display area and the fourth non-display area in sequence and are folded to extend toward the first non-display area;
and in the third non-display area and the fourth non-display area, the first touch lines are located at a side away from the display area, of the second touch lines; or
the non-display area comprises a first non-display area and a second non-display area opposite to each other, and a third non-display area and a fourth non-display area opposite to each other; wherein the first non-display area is a first non-display area binding with the chip, the third non-display area and the fourth non-display area are connected with the first non-display area and the second non-display area respectively;
the plurality of second touch lines extend from the fourth non-display area, and then folded to extend toward to the first non-display area; and
some of the first touch lines pass through the second non-display area and the third non-display area and are folded to extend toward the first on-display area, and remaining first touch lines are located in the first non-display area.

46. The display substrate according to claim 39, further comprising at least one touch chip, and the plurality of touch lines are bound and connected with the touch chip.
